(19) United States
(12) Patent Application Publication
(10) Pub. No.: US 2026/0190318 A1
(43) Pub. Date: Jul. 2, 2026

(54) SEMICONDUCTOR STRUCTURE AND MANUFACTURING METHOD THEREOF

(71) Applicant: NANYA TECHNOLOGY CORPORATION, New Taipei City (TW)

(72) Inventor: Ying-Cheng CHUANG, New Taipei City (TW)

(21) Appl. No.: 19/008,576

(22) Filed: Jan. 2, 2025

(51) Int. Cl. H10B 12/00

(52) U.S. Cl. CPC H10B 12/05; H10B 12/315

(57) ABSTRACT

In accordance with an aspect of the present disclosure, a semiconductor structure is provided. The semiconductor structure includes a substrate, a cell capacitor, a lower dielectric layer, a channel layer, a word line structure, a barrier layer, an upper dielectric layer and a spacer. The cell capacitor is embedded in the substrate. The lower dielectric layer is located on the substrate. The channel layer is located on the cell capacitor, wherein the channel layer is in direct contact with the cell capacitor and the channel layer comprises indium gallium zinc oxide (IGZO). The word line structure surrounds the channel layer. The barrier layer is located between the channel layer and the word line structure. The upper dielectric layer is located on the word line structure. The spacer is located on the sidewall of the upper dielectric layer.

### BACKGROUND

### Field of Invention

The present disclosure relates to a semiconductor structure and manufacturing method thereof.

### Description of Related Art

In recent decades, demand to storage capability has increased as electronic products continue to improve. In order to increase storage capability of a memory device (e.g., a DRAM device), more memory cells are integrated in the memory device. As the integration level increases, semiconductor structures may cause leakage issue.

### SUMMARY

In accordance with an aspect of the present disclosure, a method of manufacturing semiconductor structure is provided. The method includes following step. A substrate is provided, wherein a cell capacitor is embedded in the substrate. A lower dielectric layer and a sacrificial layer is formed on the substrate. A portion of the sacrificial layer is removed to form a first trench. A conductive layer and an upper dielectric layer is formed to fill the first trench. A portion of the upper dielectric layer is removed to form a second trench. A portion of the conductive layer is formed to define the conductive layer as a word line structure and deepen the second trench. An oxide layer is formed to fill the second trench. The sacrificial layer and a portion of the lower dielectric layer are removed to form a third trench and to expose the top surface of the cell capacitor. A channel layer is formed to fill the third trench, such that the channel layer is in direct contact with the cell capacitor.

According to some embodiments of the present disclosure, wherein after removing a portion of the sacrificial layer, a first width of the sacrificial layer is the same as a second width of the cell capacitor.

According to some embodiments of the present disclosure, further includes before forming the conductive layer and the upper dielectric layer, conformally forming a sacrificial spacer on the sacrificial layer.

According to some embodiments of the present disclosure, further includes conformally forming barrier layer on the sacrificial spacer.

According to some embodiments of the present disclosure, further includes after forming the conductive layer and the upper dielectric layer, performing a chemical mechanical polishing process.

According to some embodiments of the present disclosure, further includes after forming the conductive layer and the upper dielectric layer, forming a hard mask layer on the upper dielectric layer, and forming a photoresist layer on the hard mask layer.

According to some embodiments of the present disclosure, further includes patterning the photoresist layer and the hard mask layer, such that the photoresist layer and the hard mask layer are used as a mask when removing the portion of the upper dielectric layer.

According to some embodiments of the present disclosure, further includes forming a spacer on the sidewall of the second trench before removing the portion of the conducive layer.

According to some embodiments of the present disclosure, wherein the photoresist and the hard mask layer are removed before forming the spacer.

According to some embodiments of the present disclosure, wherein channel layer comprises indium gallium zinc oxide (IGZO).

In accordance with an aspect of the present disclosure, a semiconductor structure is provided. The semiconductor structure includes a substrate, a cell capacitor, a lower dielectric layer, a channel layer, a word line structure, a barrier layer, an upper dielectric layer and a spacer. The cell capacitor is embedded in the substrate. The lower dielectric layer is located on the substrate. The channel layer is located on the cell capacitor, wherein the channel layer is in direct contact with the cell capacitor and the channel layer comprises indium gallium zinc oxide (IGZO). The word line structure surrounds the channel layer, wherein a top surface of the word line structure is lower than a top surface of the channel layer. The barrier layer is located between the channel layer and the word line structure. The upper dielectric layer is located on the word line structure, wherein a top surface of the upper dielectric layer is coplanar with the top surface of the channel layer. The spacer is located on the sidewall of the upper dielectric layer.

According to some embodiments of the present disclosure, further includes a landing pad located on the channel layer.

According to some embodiments of the present disclosure, wherein the landing pad includes an indium tin oxide (ITO) layer located on the channel layer, and a tungsten layer on the indium tin oxide (ITO) layer.

According to some embodiments of the present disclosure, wherein a first width of the channel layer is same as a second width of the cell capacitor.

According to some embodiments of the present disclosure, further includes an oxide spacer located on the sidewall of the channel layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a cross-sectional view schematic diagram of a semiconductor structure, in accordance with some embodiments;

FIG. 1B is a top view schematic diagram of FIG. 1A, in accordance with some embodiments;

FIG. 2 is a cross-sectional view schematic diagram of a semiconductor structure after forming a lower dielectric layer and a sacrificial layer, in accordance with some embodiments;

FIG. 3A is a cross-sectional view schematic diagram of a semiconductor structure after removing a portion of the sacrificial layer, in accordance with some embodiments;

FIG. 3B is a top view schematic diagram of FIG. 3A, in accordance with some embodiments;

FIG. 4 is a cross-sectional view schematic diagram of a semiconductor structure after forming a sacrificial spacer and a barrier layer, in accordance with some embodiments;

FIG. 5 is a cross-sectional view schematic diagram of a semiconductor structure after forming a conductive layer, an upper dielectric layer, a hard mask layer, a photoresist layer, in accordance with some embodiments;

FIG. 6A is a cross-sectional view schematic diagram of a semiconductor structure after removing a portion of the photoresist layer, the hard mask layer, the upper dielectric layer, in accordance with some embodiments;

FIG. 6B is a top view schematic diagram of FIG. 6A, in accordance with some embodiments;

FIG. 7 is a cross-sectional view schematic diagram of a semiconductor structure after forming a spacer, in accordance with some embodiments;

FIG. 8A is a cross-sectional view schematic diagram of a semiconductor structure after removing a portion of the conductive layer, in accordance with some embodiments;

FIG. 8B is a top view schematic diagram of FIG. 8A, in accordance with some embodiments;

FIG. 9 is a cross-sectional view schematic diagram of a semiconductor structure after forming a oxide layer, in accordance with some embodiments;

FIG. 10 is a cross-sectional view schematic diagram of a semiconductor structure after removing the sacrificial layer and the sacrificial spacer, in accordance with some embodiments;

FIG. 11 is a cross-sectional view schematic diagram of a semiconductor structure after forming a oxide spacer, in accordance with some embodiments;

FIG. 12 is a cross-sectional view schematic diagram of a semiconductor structure after forming a IGZO (indium gallium zinc oxide) layer, in accordance with some embodiments;

FIG. 13 is a cross-sectional view schematic diagram of a semiconductor structure after forming a ITO (indium tin oxide) layer and a tungsten layer, in accordance with some embodiments; and

FIG. 14 is a cross-sectional view schematic diagram of a semiconductor structure after removing a portion of the tungsten layer and the ITO layer, in accordance with some embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

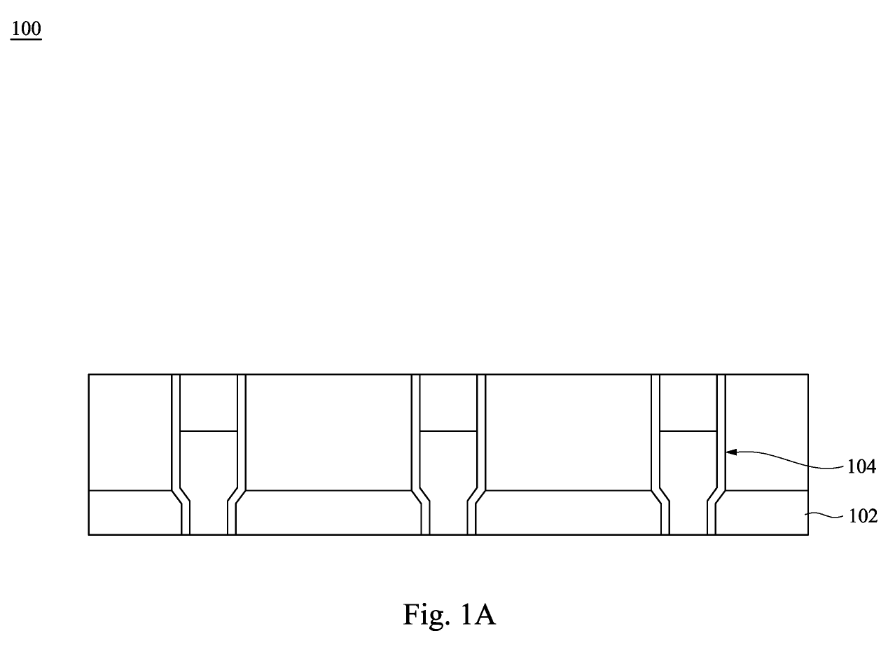

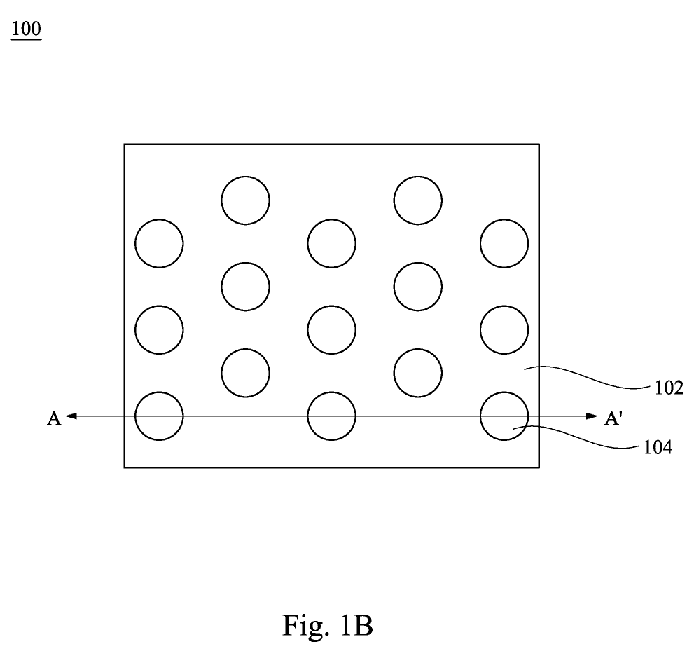

FIG. 1A to FIG. 14 are schematic diagrams of various intermediate stages in the formation of a semiconductor structure 100, in accordance with some embodiments. The semiconductor structure 100 can be applied to or part of the integrated circuit (IC), such as logic circuits, resistors, capacitors, sensors, memory device (such as dynamic random access memory (DRAM)). It should be understood that in order to simplify the graph, some components of the semiconductor structure 100 are not shown in FIG. 1A to FIG. 14, and other embodiments of the semiconductor structure 100 may include additional components.

Referring to FIG. 1A and FIG. 1B, FIG. 1A is a cross-section view along the line A-A’ of FIG. 1B. The semiconductor structure 100 includes a substrate 102. In some embodiments, the substrate 102 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the substrate 102 can be doped (e.g., containing p-type or n-type dopants) or undoped. In some embodiments, the semiconductor material of the substrate 102 may include silicon, germanium, compound semiconductors (including silicon carbide, gallium arsenide, gallium phosphide, indium phosphide, indium arsenide, and/or indium antimonide), alloy semiconductors or a combination thereof. The substrate 102 can also be formed of other materials, such as sapphire, indium tin oxide, and the like.

As shown in FIG. 1A, the substrate 102 includes a cell capacitor 104. The cell capacitor 104 is embedded in the substrate 102. In detail, the top surface of the cell capacitor 104 can be coplanar with the substrate 102. In some embodiments, the top layer of the cell capacitor 104 may include ITO or other suitable materials.

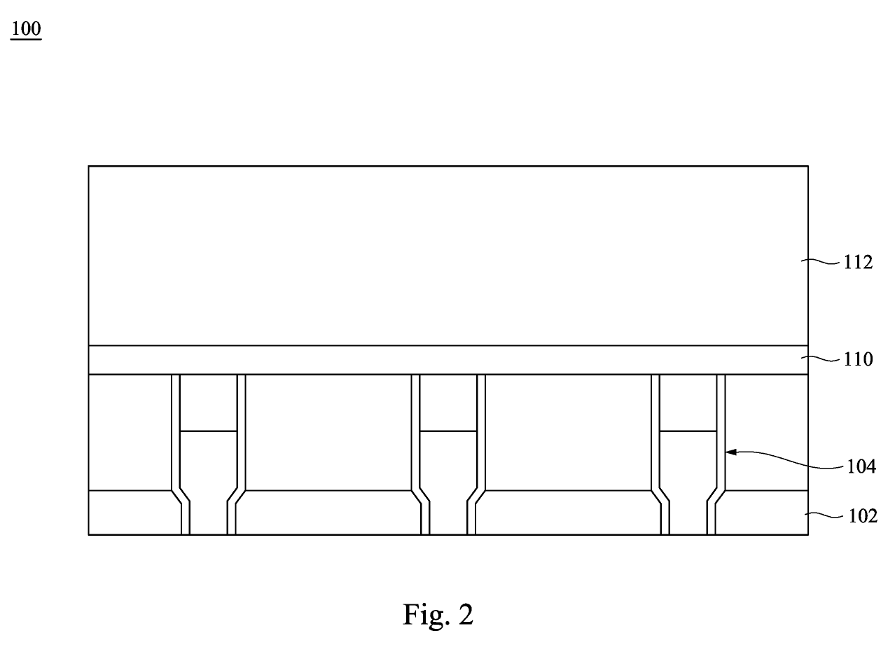

Referring to FIG. 2, a lower dielectric layer 110 is formed on the substrate 102, and a sacrificial layer 112 is formed on the lower dielectric layer 110. In some embodiments, the lower dielectric layer 110 includes oxide. In some embodiments, the sacrificial layer 112 includes polysilicon. In some embodiments, the lower dielectric layer 110 and the sacrificial layer 112 may be formed using a suitable deposition process, such as chemical vapor deposition (CVD), plasma enhanced chemical vapor deposition (PECVD), atomic layer deposition (ALD), or the like.

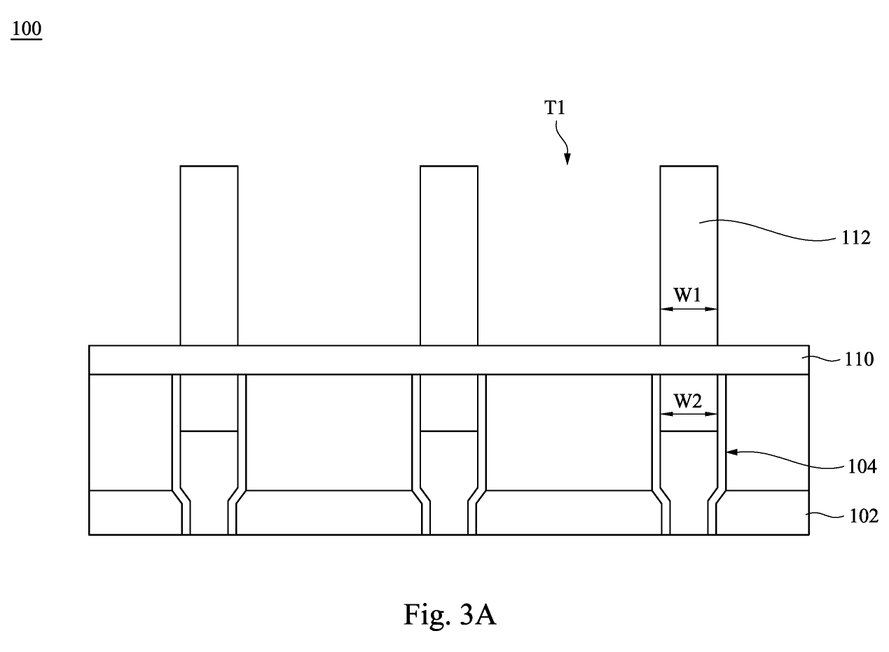

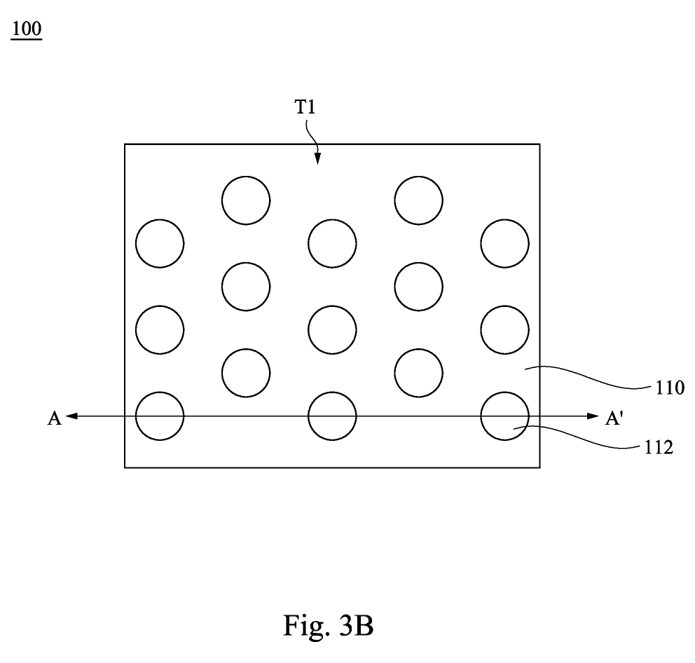

Referring to FIG. 3A and FIG. 3B, FIG. 3A is a cross-section view along the line A-A’ of FIG. 3B. A portion of the sacrificial layer 112 is removed to form a first trench T1, such that the top surface of the lower dielectric layer 110 is exposed. After removing the portion of the sacrificial layer 112, a first width W1 of the sacrificial layer 112 is substantially the same as a second width W2 of the cell capacitor 104. As shown, at this point the first trench T1 is defined by the sidewall of the sacrificial layer 112 and the top surface of the lower dielectric layer 110. In some embodiments, a photoresist (not shown) may be formed on the sacrificial layer 112 before removing a portion of the sacrificial layer 112. The photoresist may be formed by a pitch doubling process or a suitable extreme ultraviolet lithography (EUV) process. The sacrificial layer 112 may be removed using a suitable directional dry etching process, such as plasma reactive etching, ion-beam etching, or the like.

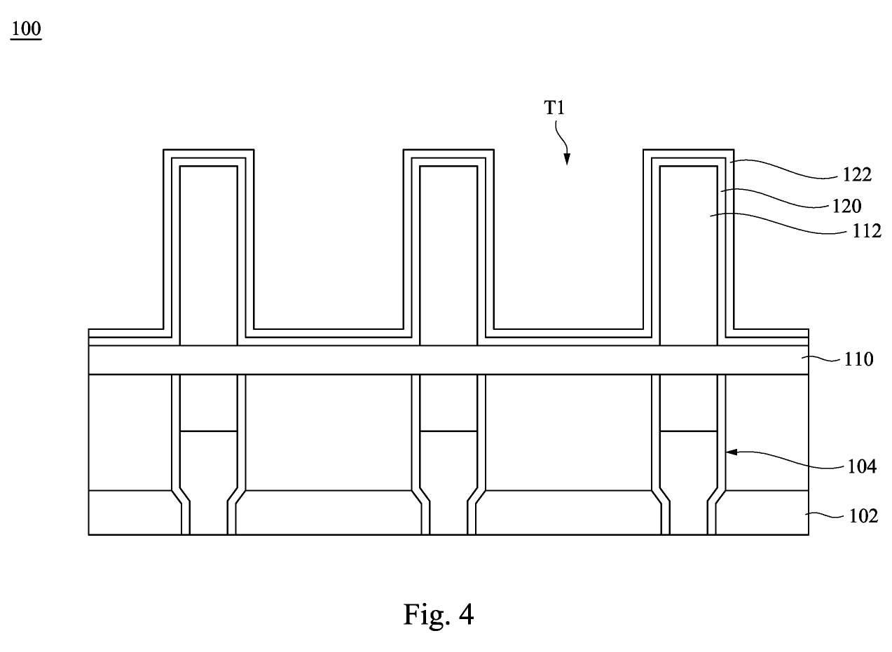

Referring to FIG. 4, a sacrificial spacer 120 is formed on the sacrificial layer 112, and a barrier layer 122 is formed on the sacrificial spacer 120. In detail, the sacrificial spacer 120 is formed on the sidewall and the top surface of the sacrificial layer 112 and the bottom surface of the first trench T1. The barrier layer 122 is formed on the sidewall and the top surface of the sacrificial spacer 120 and the bottom surface of the first trench T1. In other words, the sacrificial spacer 120 and the barrier layer 122 are conformally formed on the sacrificial spacer 120. In some embodiments, the sacrificial spacer 120 includes oxide. In some embodiments, the barrier layer 122 includes TiN (Titanium nitride). In some embodiments, the sacrificial spacer 120 and the barrier layer 122 may be formed using a suitable deposition process, such as chemical vapor deposition (CVD), plasma enhanced chemical vapor deposition (PECVD), atomic layer deposition (ALD), or the like.

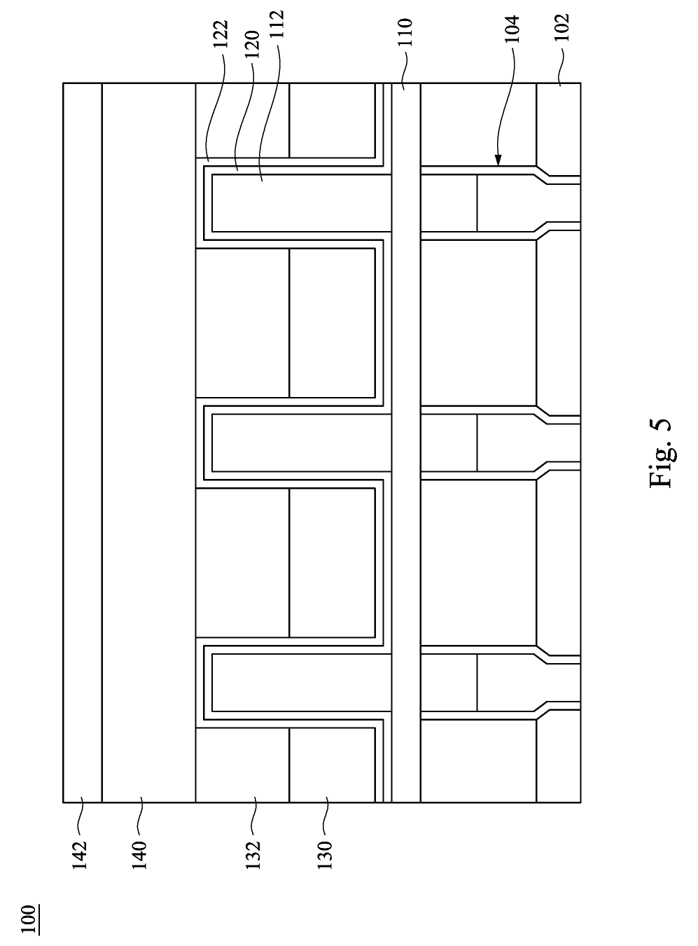

Referring to FIG. 5, a conductive layer 130 and an upper dielectric layer 132 are formed to fill the first trench T1. A hard mask layer 140 and a photoresist layer 142 are formed on the upper dielectric layer 132. After forming upper dielectric layer 132, a chemical mechanical polishing (CMP) process may be performed. In some embodiments, the conductive layer 130 includes tungsten. In some embodiments, the upper dielectric layer 132 includes oxide. In some embodiments, the hard mask layer 140 includes carbon. In some embodiments, the conductive layer 130, the upper dielectric layer 132, the hard mask layer 140, and a photoresist layer 142 may be formed using a suitable deposition process, such as chemical vapor deposition (CVD), plasma enhanced chemical vapor deposition (PECVD), atomic layer deposition (ALD), or the like.

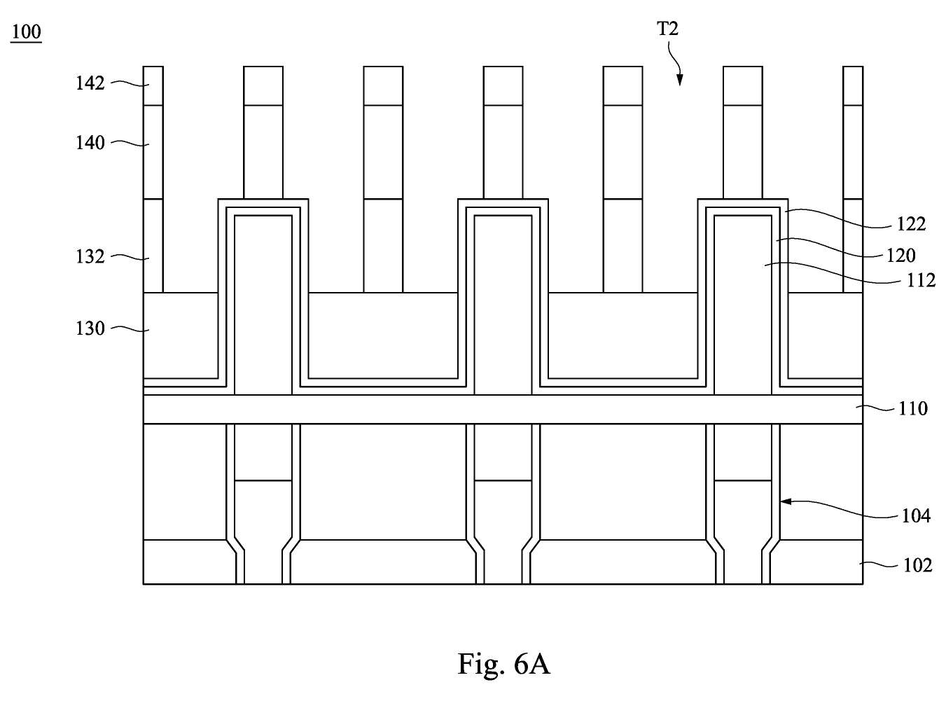

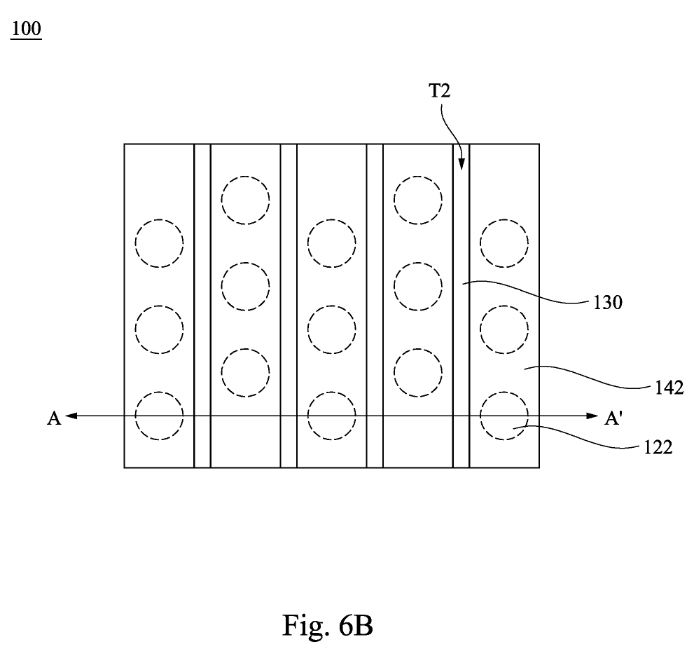

Referring to FIG. 6A and FIG. 6B, FIG. 6A is a cross-section view along the line A-A’ of FIG. 6B. A portion of the upper dielectric layer 132 is removed to form a second trench T2. In detail, the photoresist layer 142 and the hard mask layer 140 are patterned, and the photoresist layer 142 and the hard mask layer 140 are used as a mask to remove a portion of the upper dielectric layer 132. The top surface of the conductive layer 130 is exposed in the second trench T2. As shown, at this point the second trench T2 is defined by the sidewall of the barrier layer 122 and the top surface of the conductive layer 130. The upper dielectric layer 132 may be removed using a suitable directional dry etching process, such as plasma reactive etching, ion-beam etching, or the like.

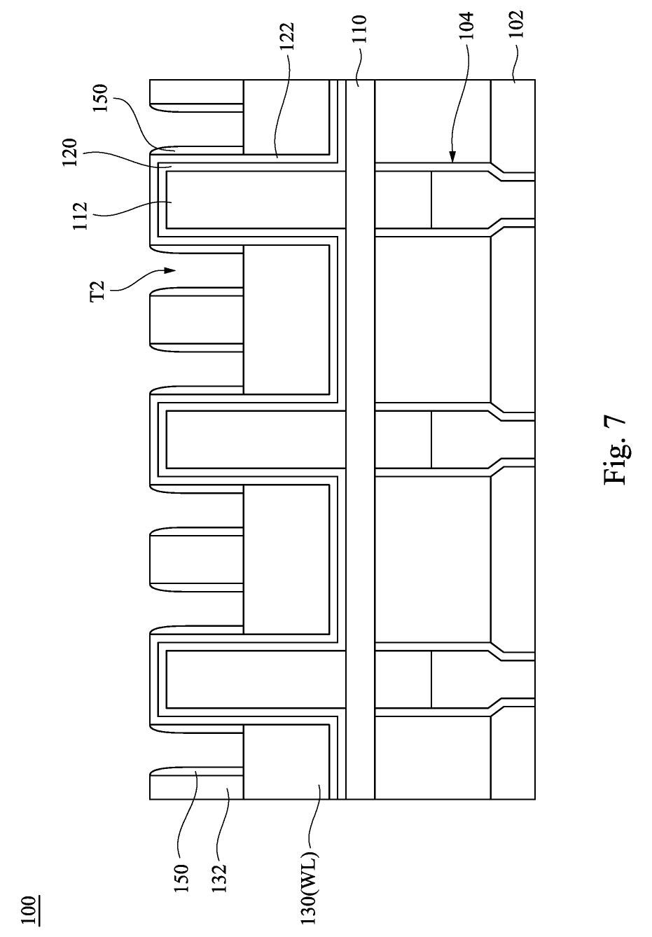

Referring to FIG. 7, a spacer 150 is formed on the sidewall of the second trench T2. In detail, the spacer 150 is formed on the barrier layer 122 and the upper dielectric layer 132. In some embodiments, the photoresist layer 142 and the hard mask layer 140 are removed before forming the spacer 150. In some embodiments, the spacer 150 has a tapered shape, such that the spacer 150 becomes thinner toward the top surface of the barrier layer 122 and the upper dielectric layer 132. As shown, at this point the second trench T2 is defined by the sidewall of the spacer 150 and the top surface of the conductive layer 130. In some embodiments, the spacer 150 may be formed using a suitable deposition process, such as chemical vapor deposition (CVD), plasma enhanced chemical vapor deposition (PECVD), atomic layer deposition (ALD), or the like.

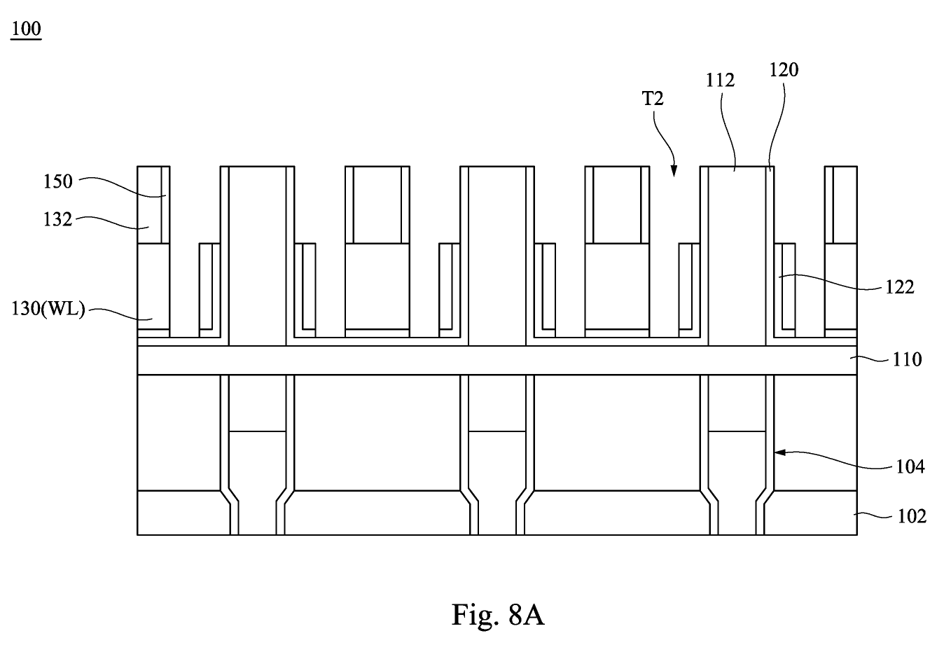

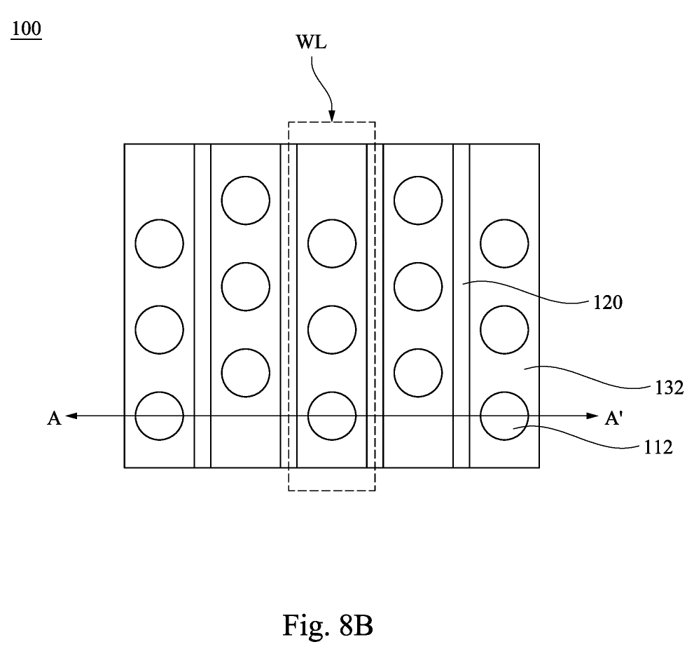

Referring to FIG. 8A and FIG. 8B, FIG. 8A is a cross-section view along the line A-A’ of FIG. 8B. A portion of the conductive layer 130 is removed to define the conductive layer 130 as a word line structure WL and to deepen the second trench T2. In detail, the barrier layer 122 and the sacrificial spacer 120 on the top surface of the sacrificial layer 112 are also removed. The spacer 150 and a portion of the barrier layer 122 on the sidewall of the second trench T2 are also removed. As shown in FIG. 8A, now the spacer 150 has a uniform thickness. After removing a portion of the conductive layer 130, a portion of the bottom dielectric layer is exposed in the second trench T2. The portion of the conductive layer 130 and the barrier layer 122 may be removed using a suitable directional dry etching process, such as plasma reactive etching, ion-beam etching, or the like.

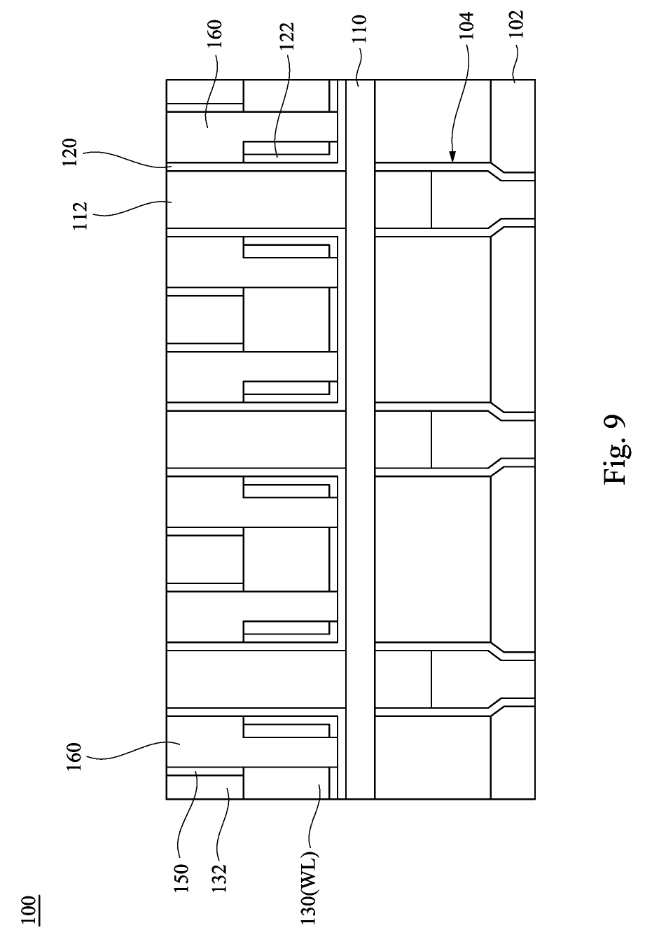

Referring to FIG. 9, an oxide layer 160 is formed to fill the second trench T2. In some embodiments, the oxide layer 160 may be formed using a suitable deposition process, such as chemical vapor deposition (CVD), plasma enhanced chemical vapor deposition (PECVD), atomic layer deposition (ALD), or the like.

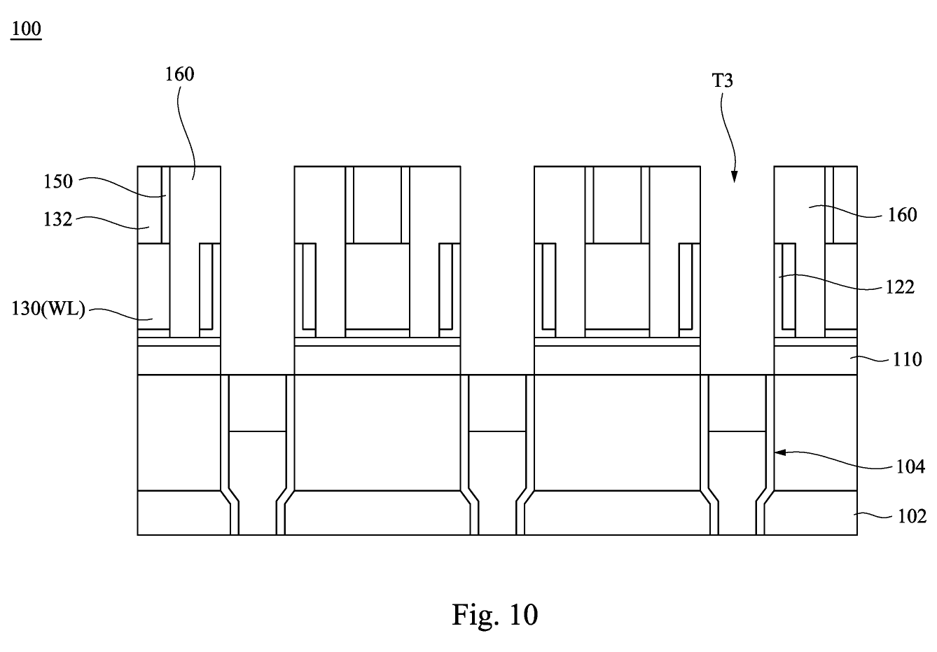

Referring to FIG. 10, the sacrificial layer 112 and the sacrificial spacer 120 are removed to form a third trench T3. In detail, a portion of the lower dielectric layer is also removed to expose the top surface of the cell capacitor 104. As shown, at this point the third trench T3 is defined by the sidewall of the oxide layer 160, the sidewall of the barrier layer 122, and the top surface of the cell capacitor 104. In some embodiments, the sacrificial layer 112 and the sacrificial spacer 120 are removed using different etching process. For example, the sacrificial layer 112 is removed by a dry etching process, and the sacrificial spacer 120 is removed by a wet etching process. In other embodiments, the sacrificial layer 112 and the sacrificial spacer 120 may both remove by a wet etching process, respectively.

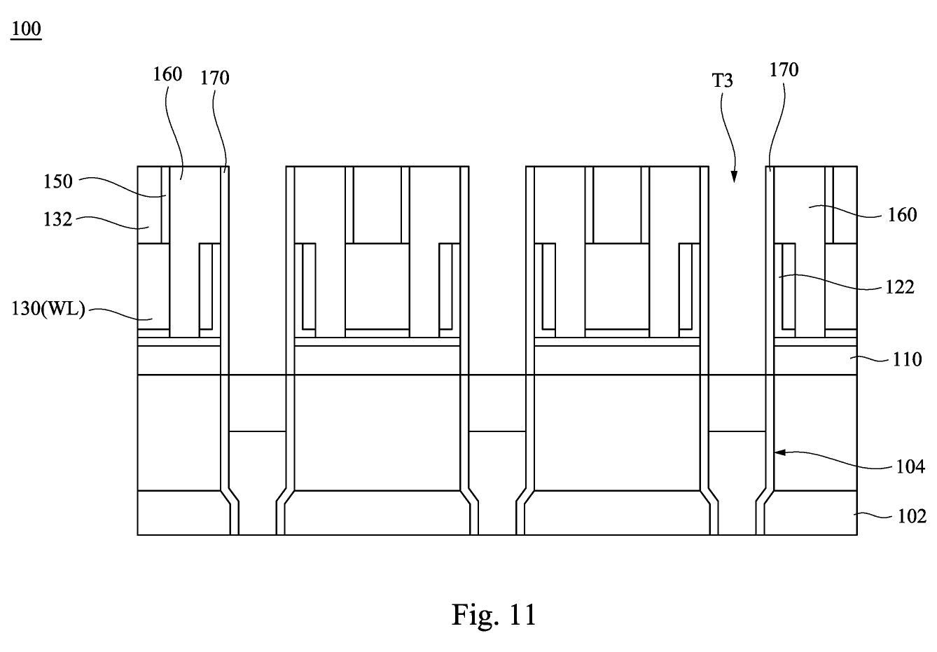

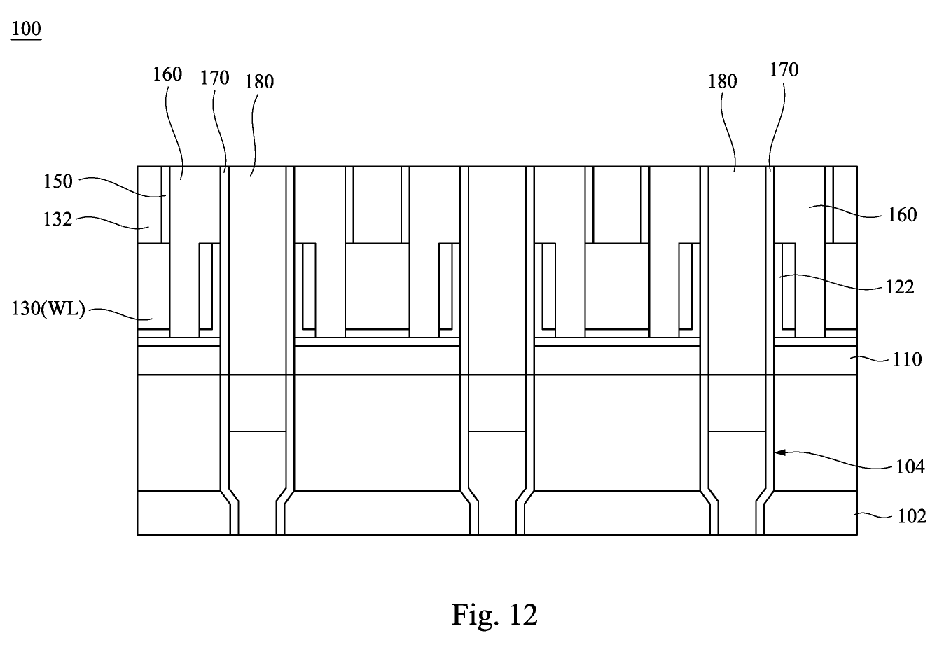

Referring to FIG. 11, an oxide spacer 170 is formed on the sidewall of the third trench T3. In detail, the oxide spacer 170 does not cover the bottom surface of the third trench T3, and a portion of the top surface of the cell capacitor 104 is still exposed in the third trench T3. Referring to FIG. 12, a channel layer 180 is formed to fill the third trench T3. The channel layer 180 is in direct contact with the cell capacitor 104. After forming the channel layer 180, a chemical mechanical polishing (CMP) process may be performed. In some embodiments, the channel layer 180 includes IGZO. In some embodiments, the oxide spacer 170 and the channel layer 180 may be formed using suitable deposition processes, such as chemical vapor deposition (CVD), plasma enhanced chemical vapor deposition (PECVD), atomic layer deposition (ALD), or the like.

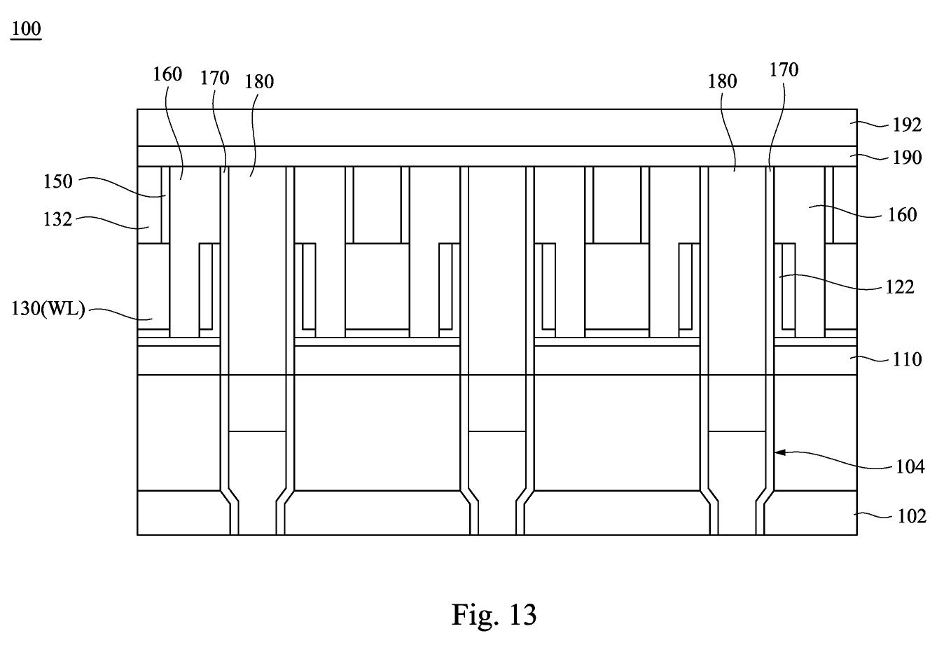

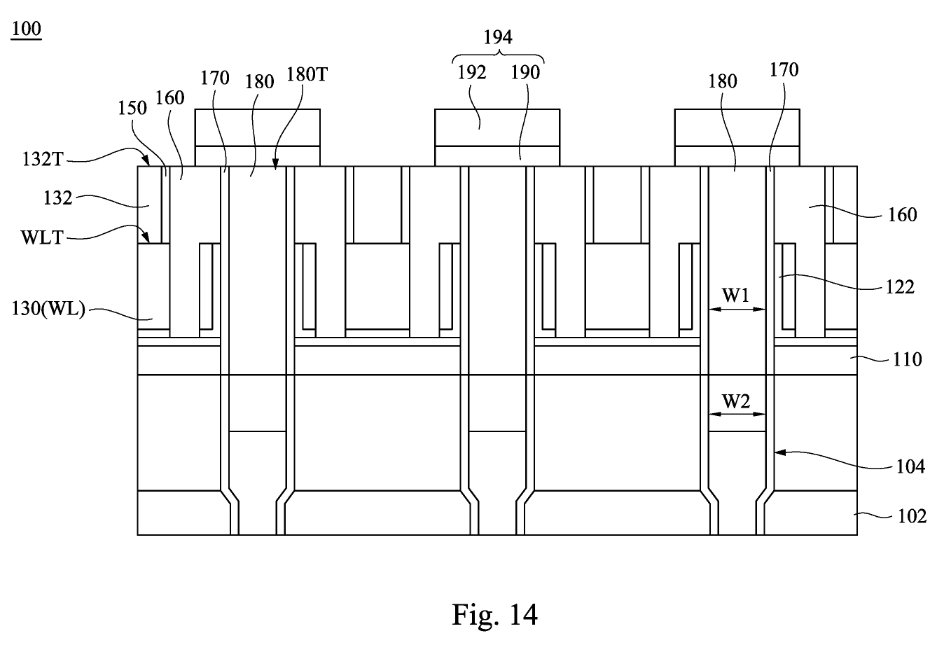

Referring to FIG. 13, an ITO layer 190 and a tungsten layer 192 are formed on the top surface of the semiconductor structure 100. For example, the ITO layer 190 and the tungsten layer are formed by physical vapor deposition (PVD). Referring to FIG. 14, a portion of the ITO layer 190 and the tungsten layer 192 are removed to form a landing pad 194. The ITO layer 190 and the tungsten layer 192 may be removed using a suitable directional dry etching process, such as plasma reactive etching, ion-beam etching, or the like.

As shown in FIG. 14, the semiconductor structure 100 includes substrate 102, cell capacitor 104, a lower dielectric layer 110, a channel layer 180, a word line structure WL, a barrier layer 122, an upper dielectric layer 132, a spacer 150, a landing pad 194, and an oxide spacer 170. The cell capacitor 104 is embedded in the substrate 102. The lower dielectric layer 110 located on the substrate 102. The channel layer 180 is located on the cell capacitor 104, wherein the channel layer 180 is in direct contact with the cell capacitor 104 and the channel layer 180 includes indium gallium zinc oxide (IGZO). The word line structure WL surrounds the channel layer 180, wherein the top surface WLT of the word line structure WL is lower than the top surface 180T of the channel layer 180. The barrier layer 122 is located between the oxide spacer 170 and the word line structure WL. The upper dielectric layer 132 located on the word line structure WL, wherein the top surface 132T of the upper dielectric layer 132 is coplanar with the top surface 180T of the channel layer 180. The spacer 150 is located on the sidewall of the upper dielectric layer 132. The landing pad 194 is located on the channel layer 180. The landing pad 194 includes an ITO layer 190 and a tungsten layer 192. The oxide spacer 170 located on the sidewall of the channel layer 180. A first width W1 of the channel layer 180 is same as a second width W2 of the cell capacitor 104.

The present disclosure provides a semiconductor structure and a manufacturing method thereof. With the method provided in this disclosure, the word line structure and the channel layer can be formed more accurately to reduce leakage issue.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing semiconductor structure, comprising:
providing a substrate, wherein a cell capacitor is embedded in the substrate;
forming a lower dielectric layer and a sacrificial layer on the substrate;
removing a portion of the sacrificial layer to form a first trench;
forming a conductive layer and an upper dielectric layer to fill the first trench;
removing a portion of the upper dielectric layer to form a second trench;
removing a portion of the conductive layer to define the conductive layer as a word line structure and deepen the second trench;
forming an oxide layer to fill the second trench;
removing the sacrificial layer and a portion of the lower dielectric layer to form a third trench and to expose the top surface of the cell capacitor; and
forming a channel layer to fill the third trench, such that the channel layer is in direct contact with the cell capacitor.

2. The method of claim 1, wherein after removing a portion of the sacrificial layer, a first width of the sacrificial layer is the same as a second width of the cell capacitor.

3. The method of claim 1, further comprising:
before forming the conductive layer and the upper dielectric layer, conformally forming a sacrificial spacer on the sacrificial layer.

4. The method of claim 3, further comprising:
conformally forming barrier layer on the sacrificial spacer.

5. The method of claim 1, further comprising:
after forming the conductive layer and the upper dielectric layer, performing a chemical mechanical polishing process.

6. The method of claim 1, further comprising:
after forming the conductive layer and the upper dielectric layer, forming a hard mask layer on the upper dielectric layer, and forming a photoresist layer on the hard mask layer.

7. The method of claim 6, further comprising:
patterning the photoresist layer and the hard mask layer, such that the photoresist layer and the hard mask layer are used as a mask when removing the portion of the upper dielectric layer.

8. The method of claim 7, further comprising:
forming a spacer on the sidewall of the second trench before removing the portion of the conducive layer.

9. The method of claim 8, wherein the photoresist layer and the hard mask layer are removed before forming the spacer.

10. The method of claim 1, wherein the channel layer comprises indium gallium zinc oxide (IGZO).

11. A semiconductor structure, comprising:
a substrate;
a cell capacitor embedded in the substrate;
a lower dielectric layer located on the substrate;
a channel layer located on the cell capacitor, wherein the channel layer is in direct contact with the cell capacitor and the channel layer comprises indium gallium zinc oxide (IGZO);
a word line structure surrounds the channel layer, wherein a top surface of the word line structure is lower than a top surface of the channel layer;
a barrier layer located between the channel layer and the word line structure;
an upper dielectric layer located on the word line structure, wherein a top surface of the upper dielectric layer is coplanar with the top surface of the channel layer; and
a spacer located on the sidewall of the upper dielectric layer.

12. The semiconductor structure of claim 11, further comprising:
a landing pad located on the channel layer.

13. The semiconductor structure of claim 12, wherein the landing pad comprises:
an indium tin oxide (ITO) layer located on the channel layer; and
a tungsten layer on the indium tin oxide (ITO) layer.

14. The semiconductor structure of claim 11, wherein a first width of the channel layer is same as a second width of the cell capacitor.

15. The semiconductor structure of claim 11, further comprising:
an oxide spacer located on the sidewall of the channel layer.
